(19) United States
(12) Patent Application Publication
(10) Pub. No.: US 2026/0182106 A1
(43) Pub. Date: Jun. 25, 2026

(54) LOW COST SEGMENTED LIGHT-EMITTING DIE ARCHITECTURE FOR DISPLAYING IMAGES AND METHOD OF OPERATION

(71) Applicant: LUMILEDS LLC, San Jose, CA (US)

(72) Inventor: Florent MONESTIER, Aachen (DE)

(73) Assignee: LUMILEDS LLC, San Jose, CA (US)

(21) Appl. No.: 18/989,678

(22) Filed: Dec. 20, 2024

(51) Int. Cl. H10H 29/14; G09G 3/32; H10H 20/812; H10H 20/813; H10H 20/825; H10H 29/01; H10H 29/24

(52) U.S. Cl. CPC H10H 29/142; G09G 3/32; H10H 20/812; H10H 20/8131; H10H 29/011; H10H 29/24; G09G 2320/064; H10H 20/825

(57) ABSTRACT

Light emitting devices and methods of operation are described herein. A lighting device includes a semiconductor die, which has rows and columns of light-emitting segments separated from one another via trenches, at least one p- or n-type contact per row, and at least one p- or n-type contact per column. The lighting device also includes a driver and a controller. The controller controls the driver to display an image on the semiconductor die by applying a bias voltage to select p- and n-type contacts corresponding to light-emitting segments that form the image.

### BACKGROUND

Liquid Crystal on Silicon (LCoS) displays and Digital Micromirror Devices (DMDs) are quickly becoming the display technology of choice in applications where size and image quality are important, such as mobile and/or wearable augmented reality (AR) and virtual reality (VR) devices. LCOS displays include a liquid crystal layer on a silicon backing, and light, such as provided by a backlight, is modulated by the orientation of the liquid crystals in response to electrical signals. This technology offers high resolutions and excellent color reproduction, making it ideal for applications requiring detailed images. DMD technology uses an array of tiny mirrors that tilt to reflect light, such as provided by a backlight, creating images by controlling the mirrors with electronic signals. DMD displays provide excellent brightness and contrast, making them suitable for dynamic content.

### SUMMARY

Light emitting devices and methods of operation are described herein. A lighting device includes a semiconductor die, which has rows and columns of light-emitting segments separated from one another via trenches, at least one p- or n-type contact per row, and at least one p- or n-type contact per column. The lighting device also includes a driver and a controller. The controller controls the driver to display an image on the semiconductor die by applying a bias voltage to select p- and n-type contacts corresponding to light-emitting segments that form the image.

### BRIEF DESCRIPTION OF THE DRAWINGS

A more detailed understanding can be had from the following description, given by way of example in conjunction with the accompanying drawings wherein:

FIG. 1A is a top view of an example LED array;

FIG. 1B is a top view of an example passive display matrix backlight;

FIG. 2A is a top view of the example passive display matrix backlight during a first time frame a of the image display period p1;

FIG. 2B is a top view of the example passive display matrix backlight during a second time frame b of the image display period p1;

FIG. 2C is a top view of the example passive display matrix backlight during a third time frame c of the image display period p1;

FIG. 2D is a top view of the example passive display matrix backlight during a fourth time frame d of the image display period p1;

FIG. 3 is a graph of the average luminous intensity B by pixel perceived by the human eye for the example passive display matrix backlight displaying the image shown in FIG. 1B over the image display period p1;

FIG. 4 is a graph showing the typical IQE drop as a function of current for an LED array where each pixel is the same color;

FIG. 5 is a diagram showing a comparison of the electrical characteristics of a single junction blue die and an ideal MQW blue die;

FIG. 6 is a flow diagram of an example method of manufacturing an example semiconductor segmented array with segmented row and column conductors;

FIG. 7A is a top view of a semiconductor die that has been etched to form an example 4×4 array of light-emitting pixels;

FIG. 7B is top view of the semiconductor die of FIG. 7A with the dielectric material deposited;

FIG. 7C is a top view of the semiconductor die of FIG. 7B with the p-contact material deposited over the pGaN regions;

FIG. 7D is a top view of the semiconductor die of FIG. 7C with the second dielectric deposited over the p-contact material;

FIG. 7E is a top view of the semiconductor die of FIG. 7D with the bonding layer deposited;

FIG. 7F is a top view of the semiconductor die of FIG. 7E with the third dielectric deposited;

FIG. 7G is a top view of the semiconductor die of FIG. 7F with the pads deposited; and

FIG. 8 is a system diagram of a display system incorporating an LED die, such as the LED die or any of the LED dies described above.

### DETAILED DESCRIPTION

Examples of different light illumination systems and/or light emitting diode (“LED”) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

It will be understood that, although the terms first, second, third, etc. may be used herein to describe various elements, these elements should not be limited by these terms. These terms may be used to distinguish one element from another. For example, a first element may be termed a second element and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

As in all mobile devices, power consumption is a key concern for micro displays, such as LCOS and DMD displays. Power consumption by such displays can, however, be mitigated, for example by recognizing that the entire field of view (FoV) of such displays does not always need to be filled. This is especially true of AR/VR devices where, for example, AR information is not required to always fill the entire FoV. When only part of the display is actively used, the overall energy required to drive the display decreases. Local dimming of the backlight used to illuminate such micro displays may therefore be an option for reducing power consumed by such devices.

In LCoS technology, for example, power consumption is at least in part tied to the number of pixels being activated and the intensity of light being modulated. By displaying content that only occupies a portion of the available resolution, fewer pixels need to be energized, leading to reduced light output requirements. This reduction can result in lower overall power consumption, as the liquid crystals require less energy to switch states. Additionally, optimizing the brightness for only the active area can further conserve power, as the backlight or illumination source does not have to work as hard to produce light across the entire display area.

For DMD micro displays, for another example, power savings can also be achieved by limiting the active area. Since DMDs rely on the tilting of micromirrors to reflect light, displaying content in a smaller region means that fewer mirrors need to be engaged at any given time. This reduces the overall energy needed to produce an image. Moreover, by using techniques like spatial light modulation, where only specific regions are illuminated based on the content being displayed, the system can conserve power while still delivering a dynamic viewing experience. By focusing on the active regions of the display and minimizing the areas that require illumination or reflection, both LCoS and DMD technologies can achieve greater energy efficiency.

A segmented LED die, also referred to herein as a monolithic LED array, is a compact arrangement of multiple light-emitting diodes (LEDs) fabricated on a single semiconductor substrate. This design allows for the integration of numerous LEDs in a unified structure, enhancing efficiency and performance. A segmented LED die may be very effective as a backlight for micro displays, such as described above, because the individual light emitters (also referred to as light-emitting segments or pixels) can be individually addressed (or addressed in groups) to selectively illuminate only the relevant part of such display, resulting in a significant reduction in the power needed to operate the display and a longer battery life for the device. Additionally, segmented LED dies are reliable sources of saturated colors and amenable to higher levels of integration, which makes them particularly well suited for micro display back lights, provided that the segmentation does not result in loss in efficacy of each segment and that the brightness of each segment can be conserved.

Segmented LED dies for mobile and/or wearable AR/VR devices are typically in the range of 5×5 pixels to 10×10 pixels, although a smaller die can be used for applications where cost is a factor and resolution is less important or a larger die can be used for better resolution. Each emitter in the die may have a size in the sub-millimeter range. The brightness or flux emitted by the segmented LED die must be high enough to compensate for optical losses of any optical system of the mobile and/or wearable device, which may include, for example, one or more lenses, beam splitters, polarizers, filters, or other optical elements, which may form an image from the energized segments and project it into the user/wearer's eye. Resolution and contrast of the segmented die can be important as the illumination needs to fit the resolution of the micro display that the segmented LED die is illuminating.

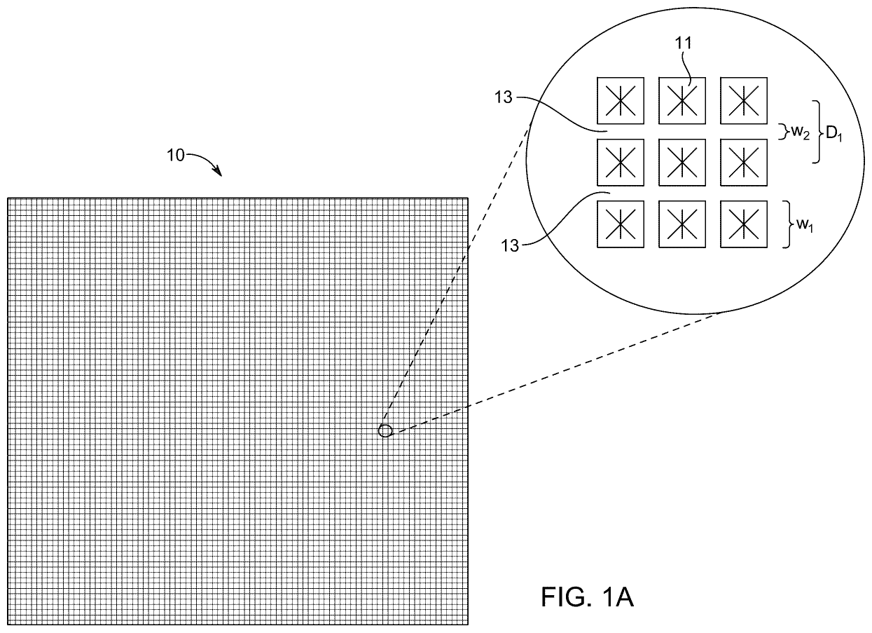

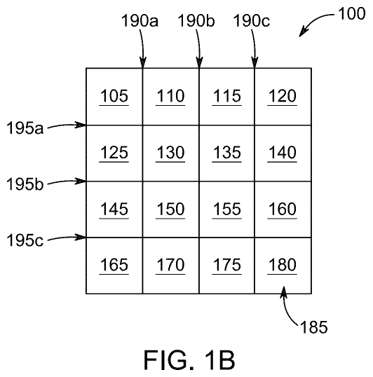

FIG. 1A is a top view of an example LED array 10. In the example illustrated in FIG. 1A, the LED array 10 is an array of emitters (or light-emitting segments) 11. Emitters 11 in the LED array 10 may be individually addressable or may be addressable in groups/subsets.

An exploded view of a 3×3 portion of the LED array 10 is also shown in FIG. 1A. As shown in the 3×3 portion exploded view, the LED array 10 may include emitters 11 that each have a width w₁. In embodiments, the width w₁ may be approximately 100 μm or less (e.g., 40 μm). Lanes 13 between the emitters 11 may be a width, w₂, wide. In embodiments, the width w₂ may be approximately 20 μm or less (e.g., 5 μm). In some embodiments, the width w₂ may be as small as 1 μm. The lanes 13 may provide an air gap between adjacent emitters or may contain other material. A distance d₁ from the center of one emitter 11 to the center of an adjacent emitter 11 may be approximately 120 μm or less (e.g., 45 μm). It will be understood that the widths and distances provided herein are examples only and that actual widths and/or dimensions may vary.

It will be understood that, although rectangular emitters arranged in a symmetric matrix are shown in FIG. 1A, emitters of any shape and arrangement may be applied to the embodiments described herein. For example, the LED array 10 of FIG. 1A may include over 20,000 emitters in any applicable arrangement, such as a 200×100 matrix, a symmetric matrix, a non-symmetric matrix, or the like. It will also be understood that multiple sets of emitters, matrixes, and/or boards may be arranged in any applicable format to implement the embodiments described herein.

As mentioned above, LED arrays, such as the LED array 10, may include up to 20,000 or more emitters. Such arrays may have a surface area of 90 mm² or greater and may require significant power to power them, such as 60 watts or more. An LED array such as this may be referred to as a micro LED array or simply a micro LED. In some embodiments, micro LEDs may include hundreds, thousands or even millions of LEDs or emitters positioned together on centimeter scale area substrates or smaller. A micro LED may include an array of individual emitters provided on a substrate or may be a single silicon wafer or die partially or fully divided into segments that form the emitters. In some embodiments, all of the emitters 11 in the array may produce the same color of light (e.g., white). Alternatively, some of the emitters 11 can emit different colors of light when powered on, such as red, green and blue, and sub-sets of the emitters 11 may controlled to tune the emitted color to a desired color. Alternatively, and preferably for the embodiments described herein, each pixel can include 2 or more light emitting regions that correspond to different colors of light emissions (e.g., a multi-quantum well (QW) emitter) when powered on, as will be described in more detail below.

In some embodiments, a controller may be coupled to selectively power subgroups of emitters (or individual multi-color emitters) in an LED array to provide different light beam patterns. At least some of the emitters in the LED array may be individually controlled through connected electrical traces. In other embodiments, groups or subgroups of emitters may be controlled together.

LED array luminaires may include light fixtures, which may be programmed to project different lighting patterns based on selective emitter activation and intensity control. Such luminaires may deliver multiple controllable beam patterns from a single lighting device using no moving parts. Typically, this is done by adjusting the brightness of individual LEDs in a 1D or 2D array. Optics, whether shared or individual, may optionally direct the light onto specific target areas. In some embodiments, the height of the LEDs, their supporting substrate and electrical traces, and associated micro-optics may be less than 5 millimeters.

LED arrays, including LED or μLED arrays, may be used to selectively and adaptively illuminate buildings or areas for improved visual display or to reduce lighting costs. In addition, such LED arrays may be used to project media facades for decorative motion or video effects. In conjunction with tracking sensors and/or cameras, selective illumination of areas around pedestrians may be possible. Spectrally distinct emitters may be used to adjust the color temperature of lighting, as well as support wavelength specific horticultural illumination.

Street lighting is an important application that may greatly benefit from use of LED arrays. A single type of LED array may be used to mimic various street light types, allowing, for example, switching between a Type I linear street light and a Type IV semicircular street light by appropriate activation or deactivation of selected emitters. In addition, street lighting costs may be lowered by adjusting light beam intensity or distribution according to environmental conditions or time of use. For example, light intensity and area of distribution may be reduced when pedestrians are not present. If emitters are spectrally distinct, the color temperature of the light may be adjusted according to respective daylight, twilight, or night conditions.

LED arrays are also well suited for supporting applications requiring direct or projected displays. For example, warning, emergency, or informational signs may all be displayed or projected using LED arrays. This allows, for example, color changing or flashing exit signs to be projected. If an LED array includes a large number of emitters, textual or numerical information may be presented. Directional arrows or similar indicators may also be provided.

Vehicle headlamps are an LED array application that may require a large number of pixels and a high data refresh rate. Automotive headlights that actively illuminate only selected sections of a roadway may be used to reduce problems associated with glare or dazzling of oncoming drivers. Using infrared cameras as sensors, LED arrays may activate only those emitters needed to illuminate the roadway while deactivating emitters that may dazzle pedestrians or drivers of oncoming vehicles. In addition, off-road pedestrians, animals, or signs may be selectively illuminated to improve driver environmental awareness. If emitters are spectrally distinct, the color temperature of the light may be adjusted according to respective daylight, twilight, or night conditions. Some emitters may be used for optical wireless vehicle to vehicle communication.

A segmented LED die architecture that may be used as a backlight for mobile/wearable applications is a segmented LED die with a common cathode where a metal grid is deposited between each pixel. Such metal grid has at least two main functions: providing electrical contacting to the n-type layer (also commonly referred to herein as n-GaN) and increasing contrast between pixels by, for example, reflecting side light. Many other segmented die options are, however, possible and usable for the embodiments described herein. For example a common anode or cathode could be used, n- and/or p-type layers could be individually contacted, contacts could be provided within the pixel area (e.g., light-emitting area) of each pixel, contacts could be provided within the streets (also referred to as grooves or trenches) between adjacent LEDs, or some combination of these technologies could be used.

One common feature of a typical segmented LED die layout, however, is that each pixel is typically individually addressed and driven using a complimentary metal-oxide-semiconductor (CMOS) backplane, which leverages CMOS technology to manage the control signals and power necessary for operating multiple LEDs. A CMOS backplane typically includes a matrix of integrated circuits or switches that can independently address each LED or group of LEDs in the array, which is also commonly referred to as active driving.

The primary function of a CMOS backplane is to provide precise control over the brightness and switching of individual LEDs, enabling features such as dimming, color mixing, and dynamic patterns. By using a multiplexing approach, the backplane can activate specific rows and columns of the LED array. The low power consumption and scalability of CMOS technology make it an ideal choice for driving large LED arrays. The ability to integrate additional features, such as sensors or communication interfaces, onto the same chip further enhances the versatility and performance of LED displays and lighting systems.

A challenge for integrating segmented LED dies into AR/VR/mobile applications is maximizing efficacy while reducing cost. While segmented LED dies with CMOS backplanes provide certain advantages in terms of speed and efficacy, they come with significant drawbacks in terms of cost and complexity of manufacture. For example, the cost of manufacturing a device comprising an AR/VR display with a segmented LED backlight is high with the cost of the CMOS panel representing more than 65% of the total cost. Additionally, the hybridization process whereby the CMOS panel is electrically coupled to the segmented LED die is extremely complex as an individual small, single, metallization pillar for each pixel must be aligned with, and connected to, individual transistors in the CMOS panel. On top of that, reliability issues may occur as the pillar interconnect between the CMOS panel and the segmented pixels is typically the weakest point, sensitive to thermal and current stress.

Embodiments described herein, therefore, provide for a segmented die architecture that makes use of passive driving, eliminating the need for a CMOS panel to drive the pixel segments. In this low-cost, segmented die architecture, the pixels may be driven passively by contacting only row and column conductors on the edges of the die, which both reduces the number of electrical contacts needed to individually drive each pixel (or group of pixels) and enables placement of a large thermal pad in the center of the die for effective heat dissipation. Using such architecture, nominal current through each pixel may be reduced along with the peak current density needed to drive the passive matrix display. A mobile lighting device, including a segmented LED die backlight (also referred to herein as a passive matrix display) and a micro-display, such as an LCoS or DMD display, may therefore be manufactured for a fraction of the cost with better thermal performance and better reliability.

As mentioned above, a passive display matrix may be used in a lighting device as a backlight for a micro-display, such as an LCoS or DMD display, to reduce the overall power consumption of the lighting device. This takes advantage of the fact that the entire display area does not need to be used to display information and, therefore, the passive display matrix may display an image that includes light sections (corresponding to segments that are powered on) and dark sections (corresponding to segments that are not powered on), which reduces power consumption since all of the segments do not need to be powered on all the time.

A passive matrix display may include row and column conductors, with each pixel in the passive matrix display being located at the intersection of one row conductor and one column conductor. To turn on a specific pixel, a bias voltage may be applied as appropriate to the particular row and column conductors for that pixel. To display an image, select pixels may be excited (or powered on by applying a bias voltage to the selected pixels) sequentially, such as by exciting selected pixels in one row or one column per time frame. By way of example, for a 3×3 passive matrix display, an image display period may be 3 time frames long, and an image may be displayed by exciting selected pixels in the first row or column in a first time frame, exciting selected pixels in the second row or column in a second time frame, and exciting selected pixels in the third row or column in a third time frame.

Using passive driving as opposed to active driving, for example, selected pixels in each row or column in a passive matrix display may only be powered on for a portion of the image display period. In the 3×3 passive display matrix described above, for example, each selected pixel is only powered on for ⅓ of the image display period. Accordingly, the switching frequency should be significantly higher than the sensitivity of the human eye (e.g., at least 100 Hz). In some embodiments, the brightness level of a displayed image may be further adjusted at the display level by adjusting the switch frequency of the display pixels (e.g., the LCoS or DMD pixel reflectivity).

When a near-field image is displayed by a passive display matrix backlight, such as described herein, a viewer will perceive the image to have a nominal brightness. However, even when a pixel is selected as part of the near-field image to be displayed, it is effectively powered off for most of the image display period. Accordingly, the brightness of each pixel should be brighter than the nominal display brightness to allow the viewer to see nominal brightness averaged over the eye sensitivity period.

FIG. 1B is a top view of an example passive display matrix backlight 100. In the example illustrated in FIG. 1B, the passive display matrix backlight 100 is a 4×4 pixel segmented LED die including 16 pixels 105, 110, 115, 120, 125, 130, 135, 140, 145, 150, 155, 160, 165, 170, 175 and 180. Each pixel includes a pixel area 185 (only one is labeled in FIG. 1B for readability), which is generally the light-emitting region of the pixel. Adjacent pixels are separated from one another via at least one horizontal trench 195a, 195b, 195c, 195a and at least one vertical trench 190a, 190b, 190c, as shown. The pixels 110, 120, 125, 140, 150, 155, 160 and 175 are part of a near-field image to be displayed by the passive display matrix backlight 100 during an image display period.

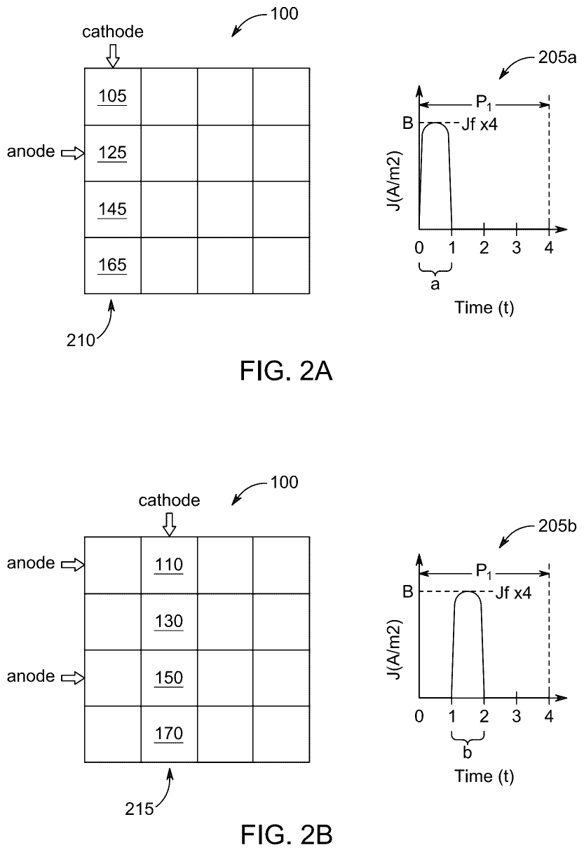

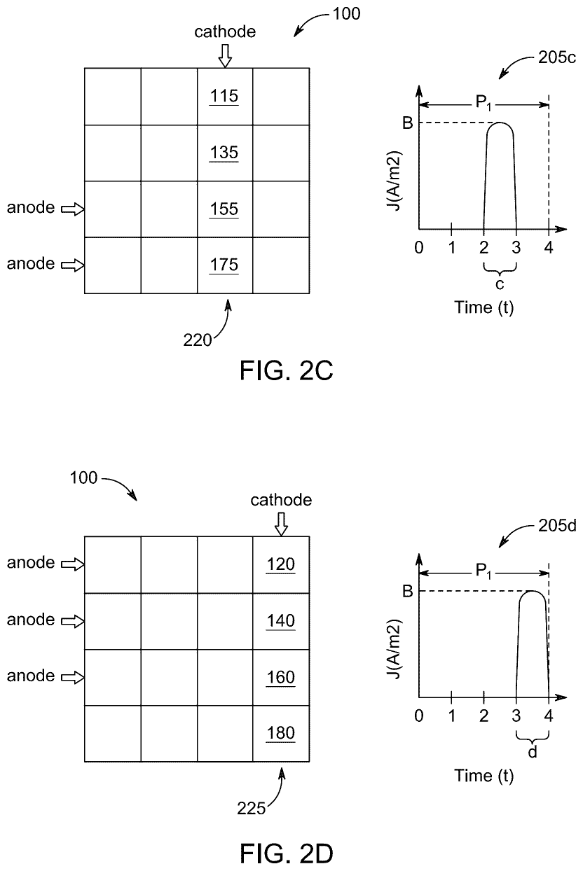

FIG. 2A is a top view of the example passive display matrix backlight 100 during a first time frame a of the image display period p1. The passive display matrix backlight 100 illustrated in FIG. 2a is configured to display the near-field image shown in FIG. 1B over a display period consisting of 4 time frames a, b, c and d. A graph 205a is also provided in FIG. 2A, which shows the current density B of the selected pixels during the first time frame a. In the example illustrated in FIG. 2A, only the pixel 125 is powered on during the first time frame a by applying a bias voltage to the appropriate row/column conductors (as described in more detail below). In FIG. 2A, the bias voltage is applied to the second column and the first and third rows.

FIG. 2B is a top view of the example passive display matrix backlight 100 during a second time frame b of the image display period p1. A graph 205b is also provided in FIG. 2B, which shows the current density B of the selected pixels during the second time frame b. In the example illustrated in FIG. 2B, pixels 110 and 150 are powered on during the second time frame b by applying a bias voltage to the appropriate row/column conductors (as described in more detail below). In the example illustrated in FIG. 2B, the bias voltage is applied to the second column and the first and third rows. Pixel 125, which was powered on during the first time frame a, is powered off during the second time frame b by discontinuing the application of the bias voltage to the associated row/column, leaving only the selected pixels 110 and 150 in the second column powered on during the second time frame b.

FIG. 2C is a top view of the example passive display matrix backlight 100 during a third time frame c of the image display period p1. A graph 205c is also provided in FIG. 2C, which shows the current density of the selected pixels during the third time frame c. In the example illustrated in FIG. 2C, pixels 155 and 175 are powered on during the third time frame c by applying a bias voltage to the appropriate row/column conductors (as described in more detail below). In the example illustrated in FIG. 2C, the bias voltage is applied to the third column and the third and fourth rows. Pixels 110 and 150, which were powered on during the second time frame b, are powered off during the third time frame c by discontinuing the application of the bias voltage to the associated row/column, leaving only the selected pixels 155 and 175 in the second column powered on during the third time frame c.

FIG. 2D is a top view of the example passive display matrix backlight 100 during a fourth time frame d of the image display period p1. A graph 205d is also provided in FIG. 2D, which shows the current density of the selected pixels during the fourth time frame d. In the example illustrated in FIG. 2D, pixels 120, 140 and 160 are powered on during the fourth time frame d by applying a bias voltage to the appropriate row/column conductors (as described in more detail below). In the example illustrated in FIG. 2D, the bias voltage is applied to the fourth column and the first, second, and third and rows. Pixels 155 and 175, which were powered on during the third time frame c, are powered off during the fourth time frame d by discontinuing the application of the bias voltage to the associated row/column, leaving only the selected pixels 120, 140 and 160 in the fourth column powered on during the fourth time frame d.

In the examples illustrated in FIGS. 2A, 2B, 2C and 2D, the column conductors are cathode conductors and the row conductors are anode conductors. The reason for this will be explained further below. However, one of ordinary skill in the art will understand that the column conductors can be anode conductors and the row conductors can be cathode conductors for applications where such change is warranted, desired or necessary for various reasons, and within the scope of the embodiments described herein.

In the example illustrated in FIGS. 1, 2A, 2B, 2C and 2D, the image of FIG. 1B (as explained above) is formed by displaying 4 partial images over 4 consecutive time frames by successively switching on selected pixels in each of 4 adjacent columns. Pixels powered on during one time frame will be powered down in the next time frame once the bias voltage applied during that one time frame is discontinued. Practically, this means that the pixels turned on during a particular time frame (e.g., time frame a, b, c or d in FIGS. 2A, 2B, 2C and 2D) will need to be brighter than they would need to be if the entire image were displayed in a single time frame (or the averaged brightness over all of the time periods in the image display period). For the example 4×4 array, the brightness B of each pixel powered on during one of the 4 time periods a, b, c or d may be approximately 4 times higher than the averaged brightness over the 4 time periods (accounting for natural variations or slight variations that would result in an image that would not be suitable for use in the intended application as would be understood by a person of ordinary skill in the art). This is shown in the graphs in FIGS. 2A, 2B, 2C and 2D where brightness is measured in energy consumed by the LED array for each individual time period a, b, c or d in Joules (J) in A/m².

While the example illustrated in FIGS. 1, 2A, 2B, 2C and 2D is with respect to applying a bias voltage to selected pixels in successive columns in the passive display matrix backlight, the embodiments described herein are applicable to applying a bias voltage to selected pixels in successive rows in the passive display matrix backlight or could even be selected out of order (i.e., not successively or partially successively).

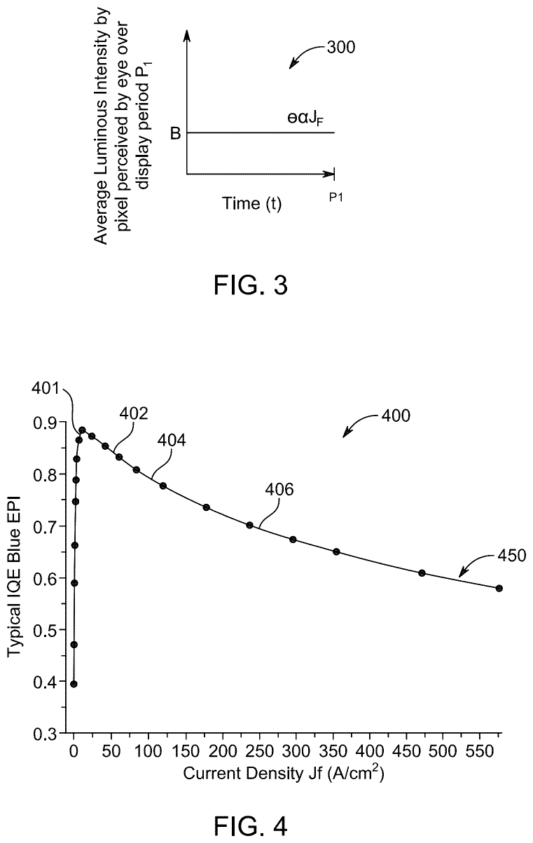

FIG. 3 is a graph of the average luminous intensity B by pixel perceived by the human eye for the example passive display matrix backlight 100 displaying the image of FIG. 1B over the image display period p1. This graph shows the amount of energy consumed by the LED array on average across the entire display period p1 in Joules (J) in A/m² and is representative of the brightness of the displayed image perceived by a viewer, which is approximately 4 times lower than the peak brightness during a given frame. While a 4×4 passive display matrix backlight is shown in FIGS. 1B, 2A, 2B, 2C and 2D, these concepts can be applied to different size matrices. For example, the bias voltage to be applied to each pixel in each time period may be determined by selecting a desired nominal brightness (as would be seen by a user of the applicable device), multiplying it by the number of rows/columns in the display matrix backlight, and applying a bias voltage that will result in the desired nominal brightness. Or in other words, these concepts can be generalized for an LED array having n×n pixels displayed over n time frames 1 to n where peak brightness is approximately n times higher than nominal brightness.

A potential issue that may arise when using passive driving to display an image using a segmented LED array, such as described above, is that higher brightness is needed per time period, which will reduce the efficacy of the lighting device. Efficacy, measured in lumens per watt (Lm/W), quantifies the efficiency of a light source in converting electrical power into visible light and represents how much light (in lumens) is produced for each watt of electrical energy consumed. A higher efficacy indicates a more efficient light source, meaning it produces more light while using less energy. For example, if an LED light source produces 800 lumens while consuming 10 watts of power, its efficacy would be 80 Lm/W. Generally, LEDs have significantly higher efficacy than traditional light sources, making them a popular choice for energy-efficient lighting solutions. Accordingly, for LED lighting applications, efficacy is an important metric as device manufacturers use this measurement to compare products, and consumers are always looking to reduce power requirements (and correspondingly shorten charge time, etc.). Efficacy can be measured in internal quantum efficacy (IQE) as a function of current.

FIG. 4 is a graph 400 showing the typical IQE drop as a function of current for an LED array where each pixel is the same color (e.g., each pixel comprises a single blue quantum well (QW) 530 epitaxial stack 500a as shown in FIG. 4). As can be seen, for the single blue QW epitaxial stack 500a, IQE drops considerably above 10 A/cm2 (represented by the point 401 on the curve 450 in FIG. 4). This is a serious concern as typical current needed to reach lighting source target illumination flux for AV/VR mobile projection applications is close to 40 A/cm2. To avoid the IQE droop effect observed at high current intensity, a sequential stack of multiple QW junctions with the same emission wavelengths (referred to herein as a multi-junction QW (MQW) die) may be used.

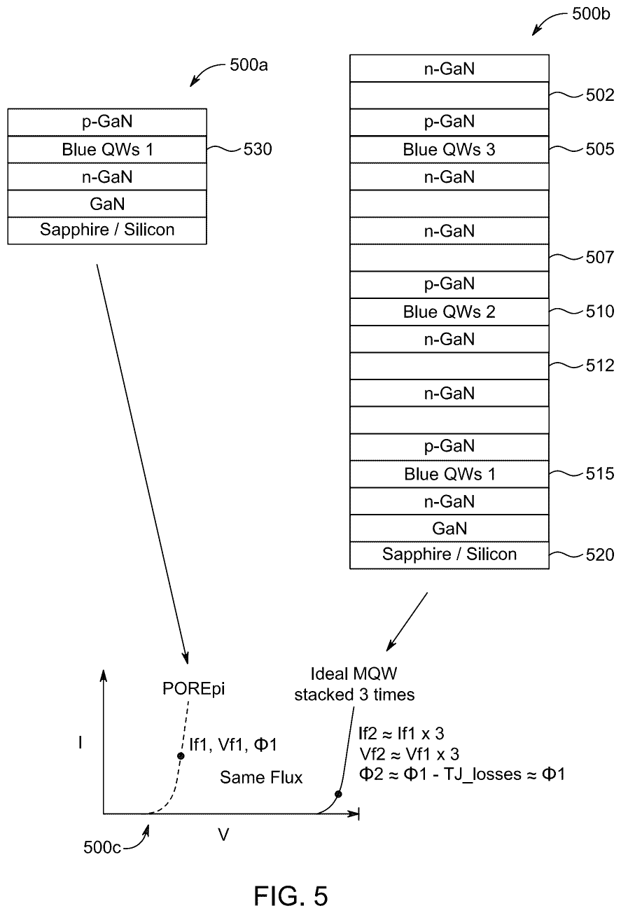

FIG. 5 is a diagram showing a comparison of the electrical characteristics of a single junction blue die 500a and an ideal MQW blue die 500b. In the example illustrated in FIG. 5, the single junction blue die 500a is shown in cross-sectional view and includes a single blue QW die 530. The ideal MQW blue die 500b, also shown in cross-section view, is a typical monochromatic InGaN epitaxial architecture with 3 light emitting regions. In the example illustrated in FIG. 5, the light-emitting regions include one or more blue QWs 505, one or more blue QWs 510, and one or more blue QWs 515. Each of the blue QWs 505, 510 and 515 is connected by a respective tunnel junction 502, 507, and 512. The epitaxial layers are grown on a substrate 520, such as a sapphire or silicon substrate. The MQW blue die 500b can be used alone or with phosphor converters over the die and/or individual light-emitting segments to make the emission appear more white, for example.

By using an MQW die, such as the MQW die 500b illustrated in FIG. 5, for the same efficacy level, the forward voltage (Vf) of an n times stacked MQW die will be n times higher than the Vf of a single junction die, such as the single QW die also illustrated in FIG. 5, but the current will be n times lower. This is illustrated by the curves in the graph 500c in FIG. 5. Accordingly, using an MQW die, such as the MQW die 500b illustrated in FIG. 5, will reduce peak current density needed to drive the LED array with passive driving, such as described above with respect to FIGS. 1B, 2A, 2B, 2C and 2D.

Returning to FIG. 4, for example, a nominal current density of a single junction die with 6 by 6 pixels driven by a CMOS backplane is approximately 40 A/cm², as indicated by point 402 on the curve 450. However, the peak current density to drive the same single junction die with 6 by 6 pixels driven in a passive driving mode, such as described above with respect to FIGS. 1B, 2A, 2B, 2C and 2D, will need to be approximately 240 A/cm2 in order to get the average of 40 A/cm2 over the time period equal to eye sensitivity, as indicated by point 404 on the curve 450. Therefore, the peak current density of a 3 times stacked MQW die, such the MQW die 500b of FIG. 5, operated with a passive driving mode, such as described above with respect to FIGS. 1B, 2A, 2B, 2C and 2D, will ideally be 240/3=80 A/cm2, as indicated by the point 406 on the curve 450. This shows that, using the 3 times stacked MQW die 500b of FIG. 5 with passive driving as described herein, as opposed to driving with a CMOS backplane, provides only a slightly lower IQE than the IQE of the single QW junction die 500a of FIG. 5.

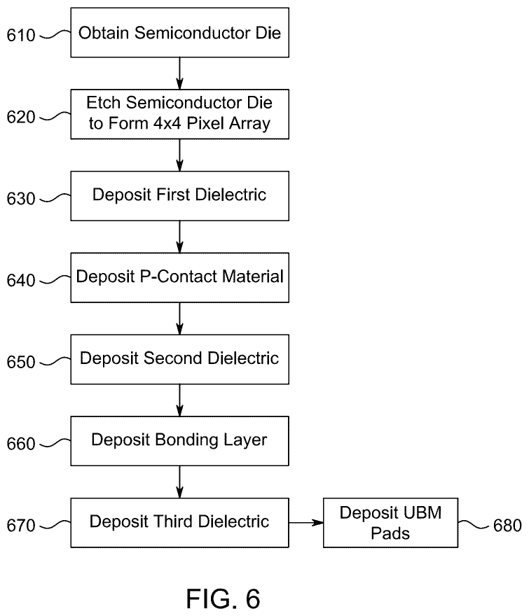

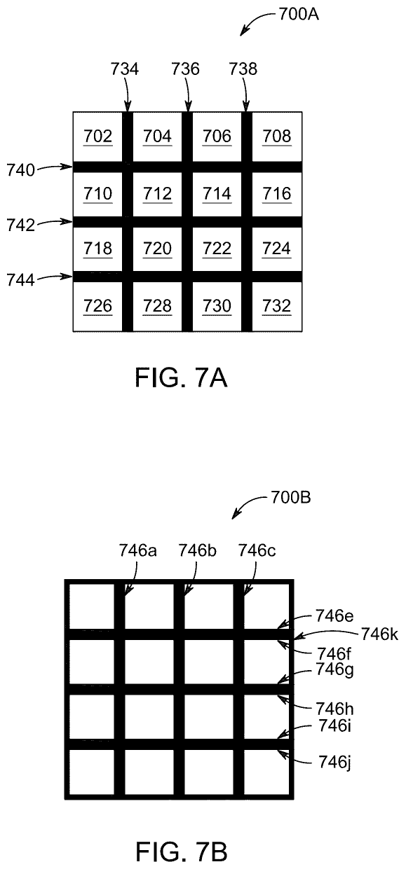

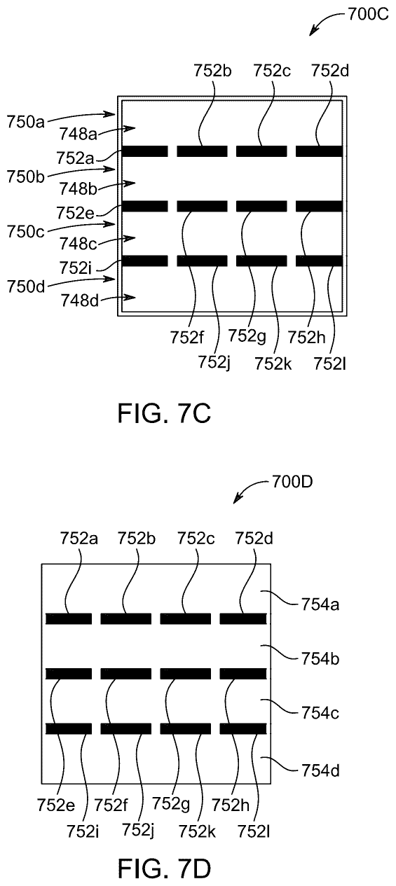

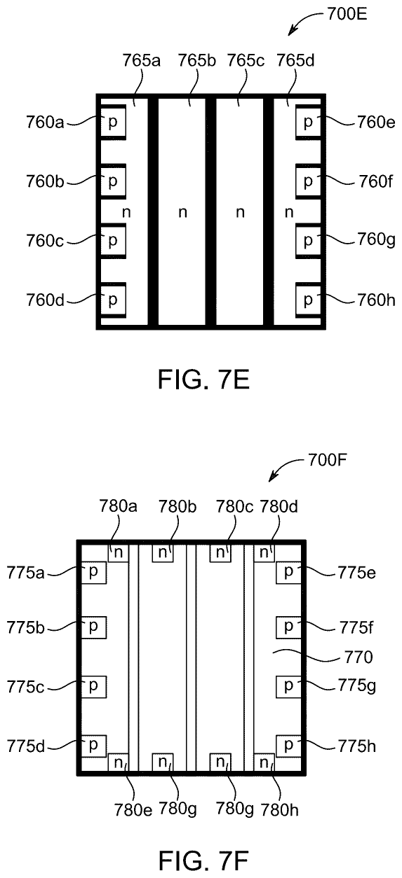

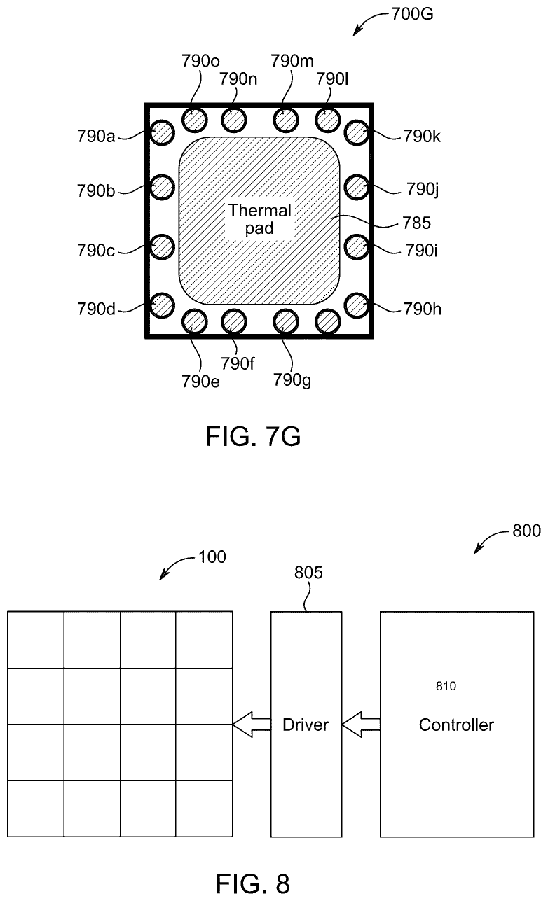

As one of ordinary skill in the art will understand, the MQW die 500b illustrated in FIG. 5 is just one example of an MQW die that may be used for any of the embodiments described herein. The IQE of the die can be adjusted along with the number of pixels in the array or number of QW junctions stacked in the MQW die, consistent with the embodiments described herein. A low cost segmented die according to any of the embodiments described herein will, therefore, have at least 3 rows of segmented anode conductors and 3 columns of segmented cathode conductors (or the other way around), and, one example embodiment, will have stacked MQW junctions to improve efficacy (although this is preferable for many embodiments, not required).
FIG. 6 is a flow diagram 600 of an example method of manufacturing an example semiconductor segmented array with segmented row and column conductors. In the example illustrated in FIG. 6, the manufacturing method may include die processing, which may form a 4×4 InGaN die with segmented row and column conductors. While this specific example is provided, it can be generalized to form any n×n semiconductor die with segmented row and column conductors, as will be understood by one of ordinary skill in the art.
A semiconductor die may be obtained (610). In some embodiments, the semiconductor die may be an InGaN die, as described above, although other types of dies suitable for use in manufacturing an n×n die, potentially with multiple stacked QWs, may be used consistent with the embodiments described herein. In some embodiments, the obtained die may already be segmented into individual light-emitting segments with corresponding n- and p-contacts (i.e., formed in the trenches or within the pixel area, as applicable).
The semiconductor die may be etched (620) to form an array of pixels. FIG. 7A is a top view 700A of a semiconductor die that has been etched to form an example 4×4 array of light-emitting pixels. As described above, one of ordinary skill in the art will understand how to generalize this method to form an n×n array, and this will not be mentioned again. In the example illustrated in FIG. 7A, the semiconductor die 700 has been etched to form 16 pGaN regions 702, 704, 706, 708, 710, 712, 714, 716, 718, 720, 722, 724, 726, 728, 730 and 732 separated by 3 vertical nGaN regions 734, 736, 738 and 3 horizonal nGaN regions 740, 742 and 744. In an MQW die, for example, n contacts electrically coupled to each of the vertically stacked QWs may be provided entirely (or almost entirely) in the streets between adjacent PGaN regions, while p contacts electrically coupled to each of the vertically stacked QWs may be provided entirely (or almost entirely) within the pixel area of each pixel. For the vertical nGaN regions 734, 736, 738, full etching of the semiconductor die can be fully etched, if desired, for example where the vertical nGaN regions 734, 736 and 738 are not used for electrical contacting but are present to separate the die into pixels.

A dielectric material may be deposited over (or directly on top of, where applicable) the vertical nGaN regions (630), around the edges of the die, and around the horizontal edges of the horizontal nGaN regions to electrically insulate those regions. FIG. 7B is top view 700B of the semiconductor die of FIG. 7A with the dielectric material deposited. In the example illustrated in FIG. 7B, the dielectric material deposited over the vertical nGaN regions is represented by 746a for the vertical nGaN region 734, 746b for the vertical nGaN region 736, and 746c for the vertical nGaN region 738. The dielectric material deposited around the edges of the semiconductor die 700 is represented by 746k. And the dielectric material deposited around the horizontal nGaN regions is represented by 746e and 746f for the horizontal nGaN region 740, 746g and 746h for the horizontal nGaN region 742, and 746i and 746j for the horizontal nGaN region 744. The horizontal nGaN regions 740, 742 and 744 are not fully covered by the dielectric material to allow electrical contacting, as described below.

A p-contact material may be deposited over the pGaN regions (640). FIG. 7C is a top view 700C of the semiconductor die of FIG. 7B with the p-contact material 748a, 748b, 748c, 748d deposited over the pGaN regions 702, 704, 706, 708, 710, 712, 714, 716, 718, 720, 722, 724, 726, 728, 730 and 732. In the example illustrated in FIG. 7C, four p-contacts 748a, 748b, 748c, and 748d are shown, each being deposited over, and electrically coupled to, a respective row of the pGaN regions 702, 704, 706, 708, 710, 712, 714, 716, 718, 720, 722, 724, 726, 728, 730 and 732. More specifically, in the illustrated example, a first p-contact 748a is disposed over, and electrically coupled to, the pGaN regions 702, 704, 706, 708 in a first row 750a; a second p-contact 748b is disposed over, and electrically coupled to, the pGaN regions 710, 712, 714, 716 in a second row 750b; a third p-contact 748c is disposed over, and electrically coupled to, the pGaN regions 718, 720, 722, 724 of a third row 750c; and a fourth p-contact 748c is disposed over, and electrically coupled to, the pGaN regions 7126, 728, 730, 732 of a fourth row 750d. The nGaN regions 734, 736, and 738 remain electrically insulated from the p-contact material 748, 748b, 748c, 748d via the dielectrics 746, and portions of the nGaN regions 740, 742, 744 remain exposed from the dielectrics 746, forming n-contact regions 752a, 752b, 752c, 752d, 752e, 752f, 752g, 752h, 752i, 752j, 752k, 752l.

In some embodiments, the p-contact material 748a, 748b, 748c, 748d may be a layer of metal, such as silver (Ag). This may be suitable for applications where cost is a factor. In some embodiments, the p-contact material 748a, 748b, 748c, 748d may be a p-mirror composite, which may include a layer of silicon dioxide (SiO₂), Ag electrical vias (eVias) and an Ag uniform layer. In such embodiments, the SiO₂ layer of the composite mirror may decrease the incident angle where total internal reflection (TIR) occurs and, therefore, increase reflectivity of the die compared with embodiments where the p-contact material include the Ag layer only. In some embodiments, the p-mirror composite may further include a distributed Bragg reflector (DBR) coating between the SiO₂ layer and the Ag uniform layer.

A dielectric may be deposited over the p-contact material (650). To distinguish from the dielectric deposited in 630, the dielectric deposited in 650 may be referred to herein as a second dielectric, although the first and second dielectric materials may be the same or different without departing from the scope of the embodiments described herein. FIG. 7D is a top view 700D of the semiconductor die of FIG. 7C with the second dielectric 754 deposited over the p-contact material 748 (not visible in FIG. 7D). Similar to the p-contact material deposition in 640, a first region 754a of the second dielectric covers the p-contact material 748a, a second region 754b of the second dielectric covers the p-contact material 748b, a third region 754c of the second dielectric covers the p-contact material 748c, and a fourth region 754d of the second dielectric covers the p-contact material 748d. While not visible in FIG. 7D, openings referred to herein as p windows on the left and right sides of each of the rows 750a, 750b, 750c, 750d remain exposed from the second dielectric, and the n-contact regions 752a, 752b, 752c, 752d, 752e, 752f, 752g, 752h, 752i, 752j, 752k, 752l also remain exposed from the second dielectric.

A bonding layer may be deposited over the second dielectric (660). FIG. 7E is a top view 700E of the semiconductor die of FIG. 7D with the bonding layer 765 deposited. The bonding layer 765 may be a thick conductor (e.g., ˜1 μm or greater in thickness), which may be or include one, or a mixture, of metal materials, such as gold (Au) and/or Ag. In the example illustrated in FIG. 7E, the bonding layer covers Ag through the p-windows to form 4 anode rows with p-contacts 760a and 760e contacting a first anode row, p-contacts 760b and 760f contacting a second anode row, p-contacts 760b and 760g contacting a third anode row, and p-contacts 760h contacting a fourth anode row. The first, second, third and fourth anode rows are not labeled in FIG. 7E for ease of viewing but can be considered to correspond to the rows 750a, 750b, 750c and 750d in FIG. 7C. Other portions of the bonding layer electrically connect the n-contact regions 752a, 752b, 752c, 752d, 752e, 752f, 752g, 752h, 752i, 752j, 752k, 752l to form four cathode columns 765a, 765b, 765c, and 765d.

A dielectric may be deposited over the bonding layer (670). To distinguish from the dielectrics deposited in 630 and 650, the dielectric deposited in 670 may be referred to herein as a third dielectric, although the first, second and third dielectric materials may be the same or different without departing from the scope of the embodiments described herein. FIG. 7F is a top view 700F of the semiconductor die of FIG. 7E with the third dielectric 770 deposited. As a result of the deposition of the third dielectric 770, only p and n contact areas of the 4 anode rows and the 4 cathode columns remain exposed from the third dielectric 770 forming p contact areas 775a, 775b, 775c, 775d, 775e, 775f, 775g, 775h for addressing the four anode rows and n contact areas 780a, 780b, 780c, 780d, 780e, 780f, 780g, 780h for addressing the four cathode rows. While the rows are described as anode rows and the columns are described as cathode rows for ease of explanation, one of ordinary skill in the art will understand that the rows may be configured as cathode rows and the columns may be configured as anode columns without departing from the scope of the embodiments described herein. Additionally, the third dielectric 770 electrically isolates the cathode columns situated in the center of the die so the center of the die may be used for heat dissipation purposes.

Pads may be deposited (680) over the p and n contact areas 775 and 780 and in the center of the die. FIG. 7G is a top view 700G of the semiconductor die of FIG. 7F with the pads deposited. The pads 790a, 790b, 790c, 790d, 790e, 790f, 790g, 790h, 790i, 790j, 790k, 790l 790m, 790n, 790o may be under bump metallization (UBM) pads, which may be thin adhesion layers followed by thick copper (Cu), gold (AU), tin (Sn), Nickel (Ni) and/or gold-tin (AuSn) layers. The pads 790 are the final electrical contacts around the edge of the die, which may be used to address the pixels in the array by row and column. A relatively large thermal pad 785 is deposited in the center of the die and is referred to as a thermal pad because it has only thermal function (i.e., it is electrically insulated from the electrical components in the die and may be used to dissipate heat generated by the LED array). The thermal pad 785 is not segmented and may cover more than 40% of the segmented die. Therefore, the thermal resistance of this die will be lower than the thermal resistance of typical segmented dies made of n by n small interconnect vias distributed over the die area. The small UBM pads 790 on the die edges will provide electrical contact to the patterned conductors of row and columns needed for passive driving.

FIG. 8 is a system diagram of a display system 800 incorporating an LED die, such as the LED die 100 or any of the LED dies described above. In the example illustrated in FIG. 8, the system includes the LED die 100, which is communicatively coupled to a driver 805. A controller 810 may generate and/or send control signals (not labeled) to control the driver 805 to supply a bias voltage to the row and column conductors of the LED die 100 to display images over discrete time periods, such as shown in FIGS. 1B, 2A, 2B, 2C and 2D and described in the corresponding written description. The system may also include a display (not shown), such as an LCoS or DMD, for which the LED die 100 may function as a backlight, such as for use in AR/VR headsets, or any other type of system where such a display may be used. In some embodiments, the LCoS or DMD and LED die 100 can be interconnected and packaged together as a hybridized device, and the controller may control both the LCoS or DMD and the LED die or multiple controllers may be included. The controller may receive information, such as information about the image to displayed, from other entities within, or external to, the display system 800, which the controller 810 may use to determine which row and column contacts to activate during which times periods. The controller may be packaged together with the LED die or hybridized device or the controller may be external to the LED die or hybridized device, such as a controller located elsewhere in an AR/VR headset or control unit, elsewhere in an automobile, or elsewhere in any device that incorporates the LED die or hybridized device. The driver will typically be packaged with the LED die with the connections already made between the die edge electrical terminals and the individual drive channels of the driver, forming a hybridized device.

LED dies, such as described above in the various embodiments, eliminate the need to connect each individual LED or group of LEDs in the die to an individual driver channel. Using such LED dies, therefore, only the terminals at the ends of the row and column conductor lines need be connected to an individual driver channel. For example, if a segmented die includes a 10×10 matrix of LEDs, it is not necessary to connect the 100 LED pixels (10×10) to 100 driver channels distributed uniformly over the die. Instead, only a minimum of 60 connections (30+30) on the die edge will be needed. In some embodiments, wire bonds or other connection methods can be used to contact the rows and columns without altering the optical performance. This passive driving segmented die configuration may, therefore, considerably simplify the manufacturing process compared to the more complex and expensive type of segmented die in which each LED must be directly connected to the driver.

In some embodiments, row and column conductors may not be provided on both sides of each row (i.e., left and right) and/or on both sides of each column (i.e., top and bottom) as it is not strictly necessary to have the contacts on all edges of the die. However, row and column conductors may be included on all edges of the die for better design symmetry and to avoid current spreading losses over the conductors.

Additionally, using the devices and method described herein, an LED can be operated in a power-efficient manner by rapidly switching it on and off so that it is perceived as being ON by a viewer. The same principle can be used to regulate the perceived brightness of an LED. In some embodiments, therefore, the driver 805 may apply pulse-width modulation (PWM) signals to adjust the brightness of an LED die. In this way, interesting effects can be achieved with relatively little effort, and an image (or a portion of an image) can be animated to some extent by pulsing its brightness, for example.

Having described the embodiments in detail, those skilled in the art will appreciate that, given the present description, modifications may be made to the embodiments described herein without departing from the spirit of the inventive concept. Therefore, it is not intended that the scope of the invention be limited to the specific embodiments illustrated and described.

What is claimed is:

1. A lighting device comprising:
a semiconductor die comprising:
a plurality of rows and columns of light-emitting segments separated from one another via trenches,
at least one p- or n-type contact per row, and
at least one p- or n-type contact per column;
a driver; and
a controller,
wherein the controller is configured to control the driver to display an image on the semiconductor die by applying a bias voltage to select p- and n-type contacts corresponding to light-emitting segments that form the image.

2. The lighting device of claim 1, wherein the controller is further configured to apply the bias voltage to the select p- and n-type contacts corresponding to the light-emitting segments that form the image by applying and removing the bias voltage to power on and off different sub-groups of the light-emitting segments that form the image over a plurality of time frames of an image display period.

3. The lighting device of claim 2, wherein each of the sub-groups comprises one or more light-emitting segments corresponding to the image in a single row or a single column.

4. The lighting device of claim 3, wherein the controller is configured to control the driver to apply and remove the bias voltage row by row or column by column over successive time frames of the image display period until each row or column of the image has been displayed.

5. The lighting device of claim 4, wherein the bias voltage is applied and removed to consecutive rows or columns over successive time frames of the image display period or to inconsecutive rows or columns over successive time frames of the image display period.

6. The lighting device of claim 4, wherein the bias voltage applied to a row or column in any time frame of the image display period is removed during the next subsequent time frame in the image display period such that only light-emitting segments corresponding to the image in a single row or column are displayed during a single time period.

7. The lighting device of claim 2, wherein each of the light-emitting segments in the semiconductor die comprises at least a first light emitting region and a second light emitting region, wherein the first light emitting region is above the second light emitting region, and each of the first and second light emitting regions is configured to emit light having the same color when powered on.

8. The lighting device of claim 1, wherein:
the first light emitting region comprises a first quantum well (QW) with a corresponding first n-type region and a corresponding first p-type region,
the second light emitting region comprises a second QW with a corresponding second n-type region and a corresponding second p-type region,
both of the first and second n-type regions are electrically coupled to the n-type contact, and
both of the first and second p-type regions are electrically coupled to the p-type contact.

9. The lighting device of claim 4, wherein the bias voltage applied to each of the p- and n-type contacts during each of the plurality of time frames has a magnitude large enough to cause each sub-group powered on during a single time frame to have a brightness 4 times higher than a specified average brightness across all light-emitting segments that form the image if all light-emitting segments in the image were powered on for the entire image display period.

10. The lighting device of claim 9, wherein the controller is further configured to adjust the brightness over one or more image display periods by controlling the driver to apply pulse width modulated (PWM) signals to the LED die.

11. The lighting device of claim 1, wherein:
the at least one p- or n-type contact per column comprises at most two n-type contacts per column electrically coupled to the n-type region of each of the light-emitting segments in the corresponding row, and
the at least one p- or n-type contact per row comprises at most two p-type contacts per row electrically coupled to the p-type region of each of the light-emitting segments in the corresponding column.

12. A method of displaying an image, on a semiconductor die comprising a plurality of rows and columns of light-emitting segments separated from one another via trenches, at least one p- or n-type contact per row, and at least one p- or n-type contact per column, the method comprising:
applying a bias voltage to select p- and n-contacts corresponding to light-emitting segments that form the image.

13. The method of claim 12, wherein the applying the bias voltage further comprises applying the bias voltage to the select p- and n-type contacts corresponding to the light-emitting segments that form the image by applying and removing the bias voltage to power on and off different sub-groups of the light-emitting segments that form the image over a plurality of time frames of an image display period.

14. The method of claim 13, wherein each of the sub-groups comprises one or more light-emitting segments corresponding to the image in a single row or a single column.

15. The method of claim 14, wherein the applying and removing the bias voltage further comprises applying and removing the bias voltage row by row or column by column over successive time frames of the image display period until each row or column of the image has been displayed.

16. The lighting device of claim 15, wherein the bias voltage is applied and removed to consecutive rows or columns over successive time frames of the image display period or to inconsecutive rows or columns over successive time frames of the image display period.

17. The method of claim 15, wherein the bias voltage applied to a row or column in any time frame of the image display period is removed during the next subsequent time frame in the image display period such that only light-emitting segments corresponding to the image in a single row or column are displayed during a single time period.

18. The method of claim 13, wherein the bias voltage applied to each of the p- and n-type contacts during each of the plurality of time frames has a magnitude large enough to cause each sub-group powered on during a single time frame to have a brightness 4 times higher than a specified average brightness across all light-emitting segments that form the image if all light-emitting segments in the image were powered on for the entire image display period.

19. The method of claim 18, further comprising adjusting the brightness over one or more image display periods by applying pulse width modulated (PWM) signals to the LED die.
